(19) United States
(12) Patent Application Publication
(10) Pub. No.: US 2025/0287522 A1
(43) Pub. Date: Sep. 11, 2025

(54) CHASSIS, CARRIAGE AND LOCK MODULE

(71) Applicant: Wistron Corporation, New Taipei City (TW)

(72) Inventors: Kuan-Yi Liu, New Taipei City (TW); Chu-Chang Huang, New Taipei City (TW)

(73) Assignee: Wistron Corporation, New Taipei City (TW)

(21) Appl. No.: 18/600,797

(22) Filed: Mar. 11, 2024

(30) Foreign Application Priority Data
Dec. 1, 2023 (TW) 112146758

(51) Int. Cl. H05K 7/14

(52) U.S. Cl. CPC H05K 7/1427; H05K 7/1401

(57) ABSTRACT

A chassis includes a casing and a carriage. The casing has an engaging portion. The carriage includes a housing and a lock module. The lock module includes a bracket, a damping member, a fixing structure and a lock member. The bracket has an accommodating portion and an engaging recess. The damping member is disposed in the accommodating portion. The damping member has a hole portion. The fixing structure is disposed in the hole portion. The lock module is fixed on the housing via the fixing structure. The lock member is movably disposed on the bracket. When the engaging portion is located in the engaging recess and the lock member is located in the engaging recess, the lock member restrains the engaging portion in the engaging recess to lock the carriage on the casing.

### BACKGROUND OF THE INVENTION

### 1. Field of the Invention

The disclosure relates to a chassis, a carriage and a lock module and, more particularly, to a lock module having vibration damping function and capable of being assembled or disassembled conveniently, and a chassis and a carriage equipped with the lock module.

### 2. Description of the Prior Art

The current structural design of servers often fixes a mother board or other circuit boards (e.g. printed circuit board assembly (PCBA)) on a tray, and then assembles the tray to a casing of a chassis. In order to facilitate disassembly and assembly, the tray usually adopts a toolless design, such that the tray and the casing of the chassis cannot be tightly fixed. During shock and vibration test, vibrations will be transmitted to the tray through the casing of the chassis, thereby causing solder crack or other damages on the circuit board.

### SUMMARY OF THE INVENTION

The disclosure provides a lock module having vibration damping function and capable of being assembled or disassembled conveniently, and a chassis and a carriage equipped with the lock module, so as to solve the aforesaid problems.

According to an embodiment of the disclosure, a chassis comprises a casing and a carriage. The casing has an engaging portion. The carriage comprises a housing and a lock module. The lock module comprises a bracket, a damping member, a fixing structure and a lock member. The bracket has an accommodating portion and an engaging recess. The damping member is disposed in the accommodating portion. The damping member has a hole portion. The fixing structure is disposed in the hole portion. The lock module is fixed on the housing via the fixing structure. The lock member is movably disposed on the bracket. When the engaging portion is located in the engaging recess and the lock member is located in the engaging recess, the lock member restrains the engaging portion in the engaging recess to lock the carriage on the casing.

According to another embodiment of the disclosure, a carriage comprises a housing and a lock module. The lock module comprises a bracket, a damping member, a fixing structure and a lock member. The bracket has an accommodating portion and an engaging recess. The damping member is disposed in the accommodating portion. The damping member has a hole portion. The fixing structure is disposed in the hole portion. The lock module is fixed on the housing via the fixing structure. The lock member is movably disposed on the bracket.

According to another embodiment of the disclosure, a lock module comprises a bracket, a damping member, a fixing structure and a lock member. The bracket has an accommodating portion and an engaging recess. The damping member is disposed in the accommodating portion. The damping member has a hole portion. The fixing structure is disposed in the hole portion. The lock member is movably disposed on the bracket.

As mentioned in the above, the disclosure disposes the damping member between the bracket and the fixing structure to isolate the bracket from the fixing structure by the damping member. The damping member is capable of effectively absorbing vibrations transmitted from the casing of the chassis and the bracket, so as to reduce the vibration energy transmitted from the casing of the chassis to the carriage. Accordingly, the disclosure can prevent vibration from causing damage to a circuit board fixed on the carriage. Furthermore, the lock module restrains the engaging portion in the engaging recess by the lock member, so as to lock the carriage on the casing. As long as the lock member moves away from the engaging recess, the engaging member is able to disengage from the engaging recess, so as to detach the carriage from the casing. Accordingly, a user can conveniently and rapidly disassemble or assemble the carriage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded view illustrating a chassis according to an embodiment of the disclosure.

FIG. 2 is a partial perspective view illustrating the chassis shown in FIG. 1.

FIG. 3 is a perspective view illustrating a lock module shown in FIG. 2 from another viewing angle.

FIG. 4 is an exploded view illustrating the lock module shown in FIG. 3.

FIG. 5 is a perspective view illustrating an operating member shown in FIG. 3 moving to a first position.

FIG. 6 is a perspective view illustrating a carriage shown in FIG. 1 being put into a casing.

FIG. 7 is a partial perspective view illustrating the chassis shown in FIG. 6.

FIG. 8 is a perspective view illustrating the operating member shown in FIG. 6 moving to the first position.

FIG. 9 is a partial perspective view illustrating the chassis shown in FIG. 8.

FIG. 10 is a front view illustrating a lock module according to another embodiment of the disclosure.

FIG. 11 is a front view illustrating the engaging portion pushing the lock member to rotate and moving into the engaging recess.

FIG. 12 is a front view illustrating the engaging portion pushing the lock member to rotate and moving out of the engaging recess.

FIG. 13 is a perspective bottom view illustrating the lock module shown in FIG. 10.

### DETAILED DESCRIPTION

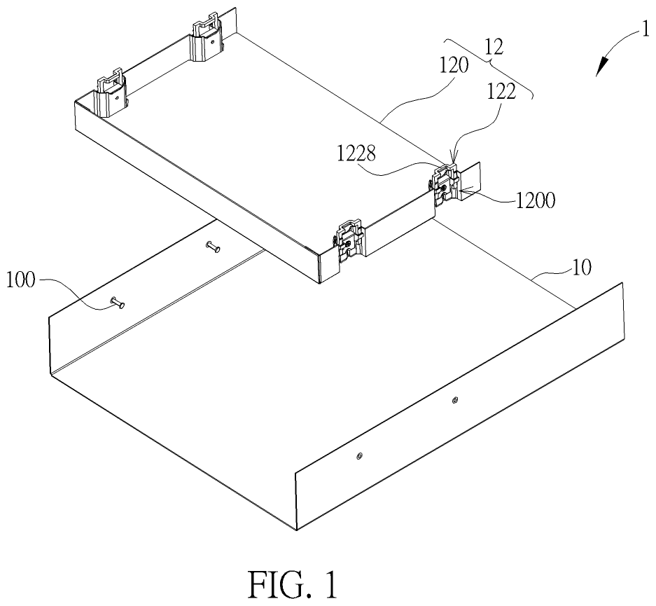

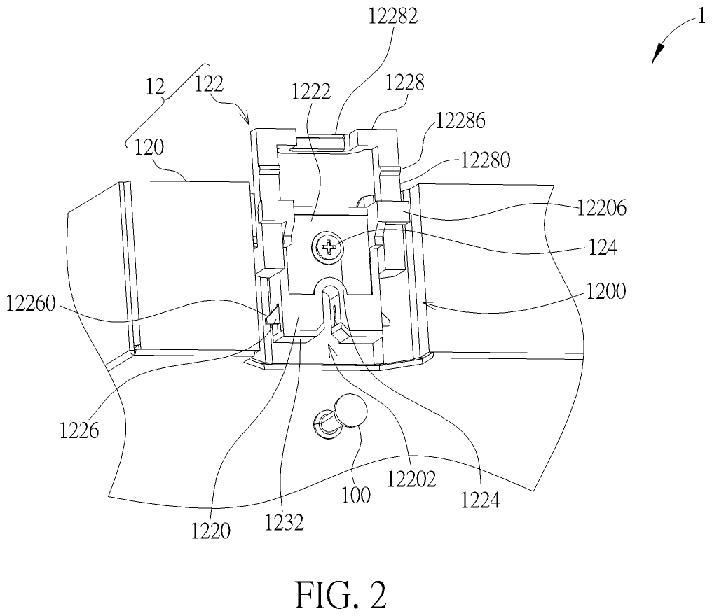

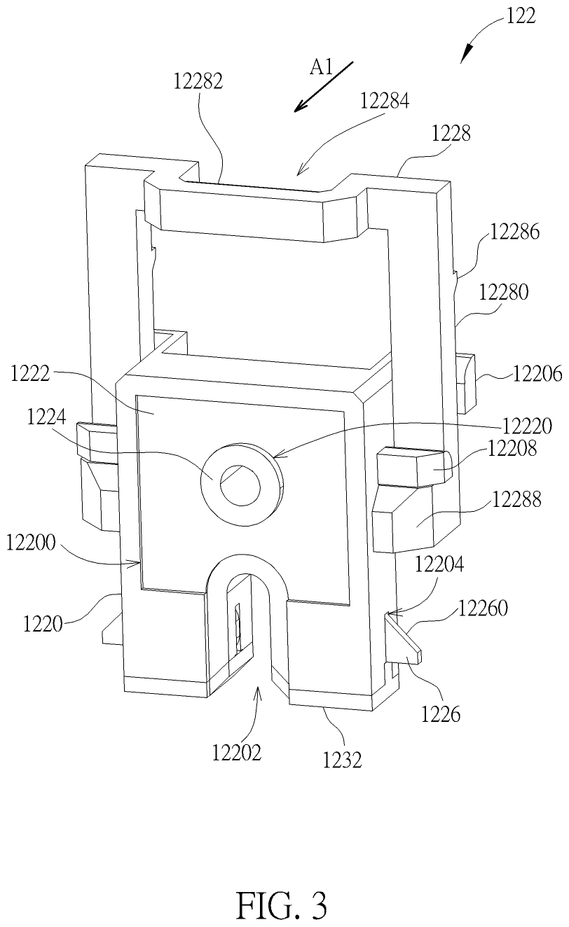

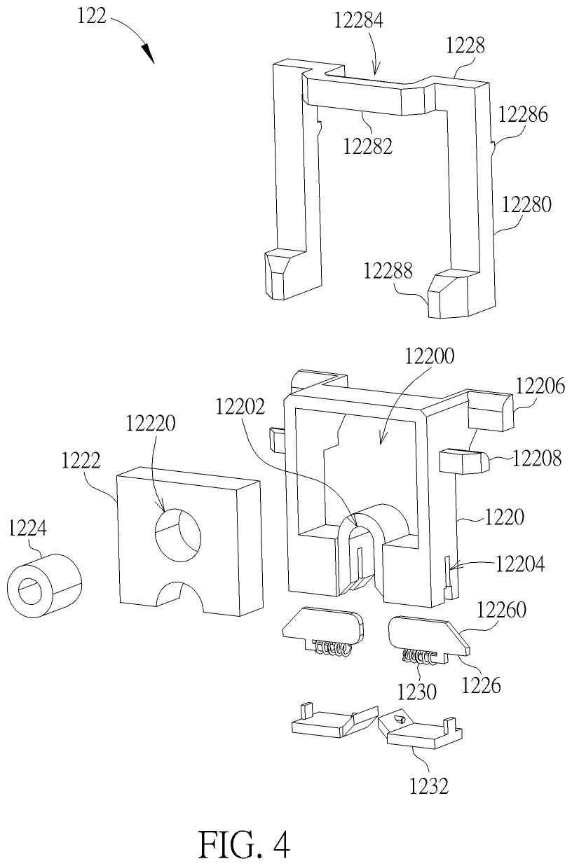

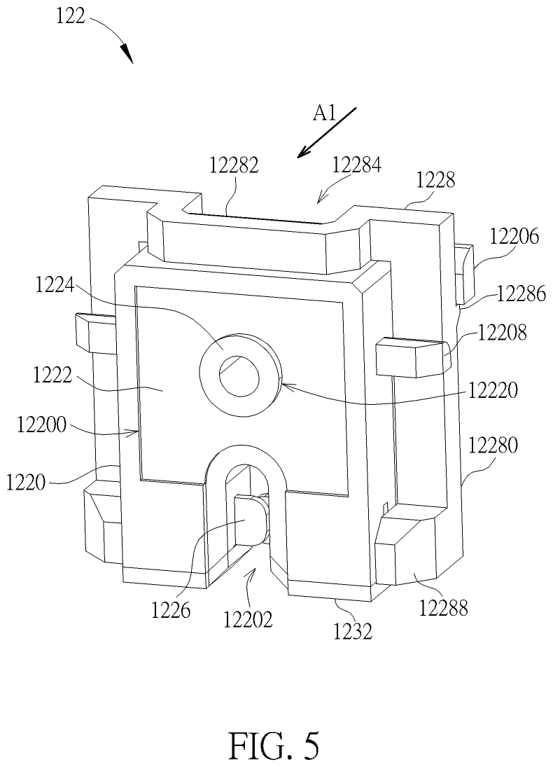

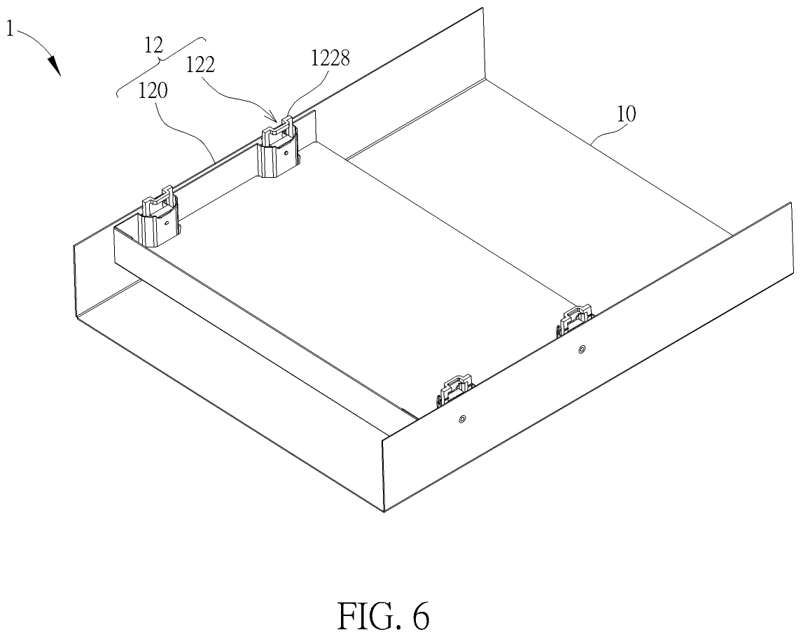

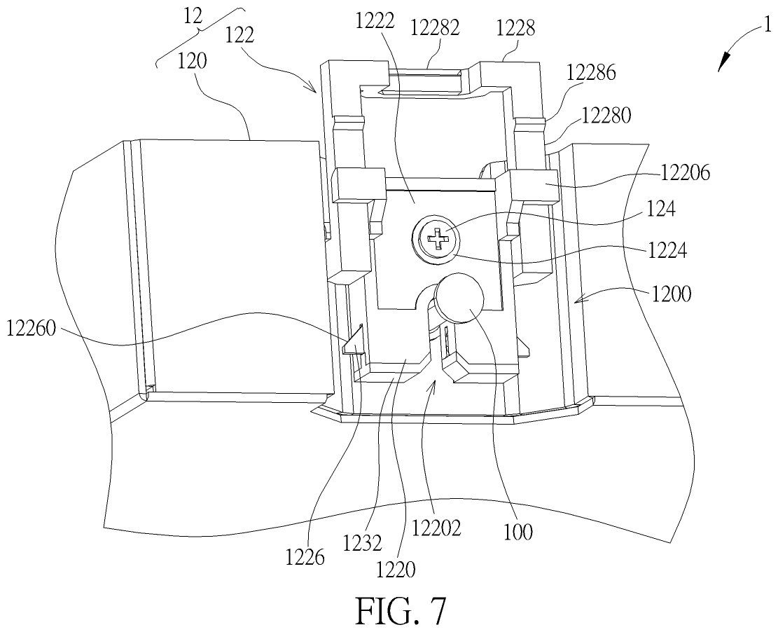

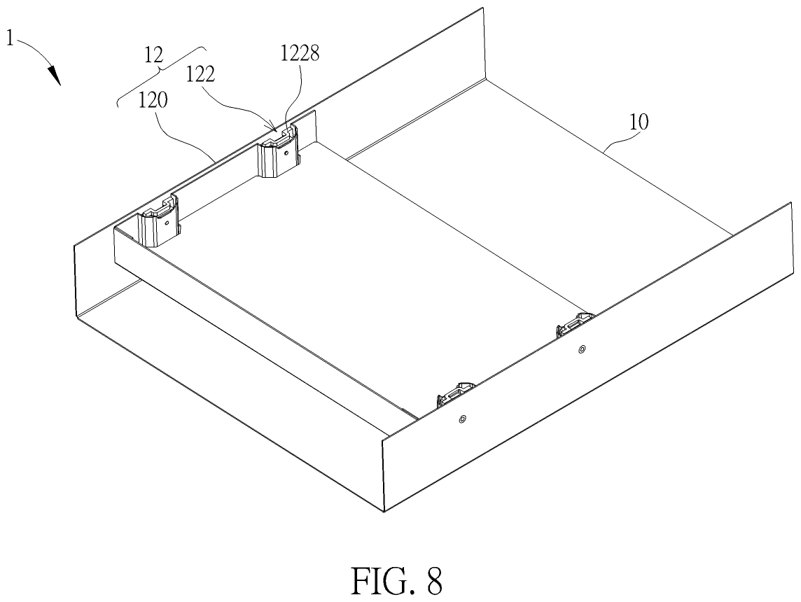

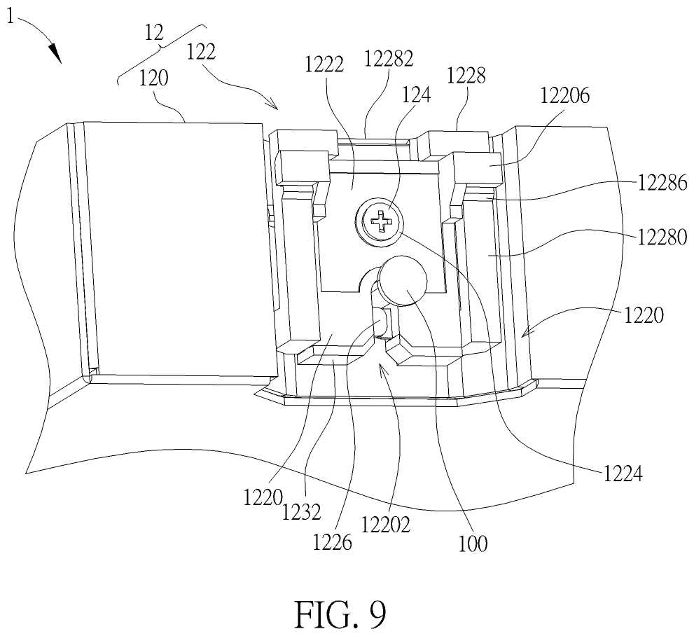

Referring to FIGS. 1 to 9, FIG. 1 is an exploded view illustrating a chassis 1 according to an embodiment of the disclosure, FIG. 2 is a partial perspective view illustrating the chassis 1 shown in FIG. 1, FIG. 3 is a perspective view illustrating a lock module 122 shown in FIG. 2 from another viewing angle, FIG. 4 is an exploded view illustrating the lock module 122 shown in FIG. 3, FIG. 5 is a perspective view illustrating an operating member 1228 shown in FIG. 3 moving to a first position, FIG. 6 is a perspective view illustrating a carriage 12 shown in FIG. 1 being put into a casing 10, FIG. 7 is a partial perspective view illustrating the chassis 1 shown in FIG. 6, FIG. 8 is a perspective view illustrating the operating member 1228 shown in FIG. 6 moving to the first position, and FIG. 9 is a partial perspective view illustrating the chassis 1 shown in FIG. 8.

As shown in FIGS. 1 and 2, the chassis 1 comprises a casing 10 and a carriage 12. It should be noted that the casing 10 shown in FIG. 1 is only a part of a complete casing of the chassis 1. The chassis 1 may be a chassis of a server or other devices according to practical applications. The casing has an engaging portion 100. In this embodiment, the casing 10 may have four engaging portions 100 respectively disposed at two sides of the casing 10. The carriage 12 comprises a housing 120 and a lock module 122. In this embodiment, the carriage 12 may comprise four lock modules 122 respectively disposed at two sides of the housing 120, wherein the positions of the four lock modules 122 respectively correspond to the positions of the four engaging portions 100. It should be noted that the number and position of the lock modules 122 and the engaging portions 100 may be determined according to practical applications, so the disclosure is not limited to the embodiment shown in the figure. In this embodiment, two sides of the housing 120 may have four recesses 1200 for accommodating the four lock modules 122. In this embodiment, the carriage 12 may be a tray and the lock module 122 may be disposed on a side wall of the tray, but the disclosure is not so limited.

As shown in FIGS. 2 to 5, the lock module 122 comprises a bracket 1220, a damping member 1222, a fixing structure 1224, a lock member 1226, an operating member 1228, an elastic member 1230 and a cover 1232. The bracket 1220 has an accommodating portion 12200 and an engaging recess 12202. The damping member 1222 is disposed in the accommodating portion 12200 of the bracket 1220 and the damping member 1222 has a hole portion 12220. The fixing structure 1224 is disposed in the hole portion 12220 of the damping member 1222, such that the damping member 1222 isolates the bracket 1220 from the fixing structure 1224. The bracket 1220 and the fixing structure 1224 may be made of aluminum alloy or other materials. The damping member 1222 may be made of rubber or other materials capable of absorbing vibration. For example, when the damping member 1222 is made of rubber, the bracket 1220, the damping member 1222 and the fixing structure 1224 may be jointed during rubber molding process, but the disclosure is not so limited.

The lock module 122 is fixed on the housing 120 via the fixing structure 1224. As shown in FIG. 2, a fixing member 124 (e.g. screw) may be inserted into the fixing structure 1224 and fixed to the housing 120, so as to fix the lock module 122 on the housing 120. After the lock module 122 is fixed on the housing 120, the bracket 1220 is not in contact with the housing 120.

The lock member 1226 is movably disposed on the bracket 1220 and corresponds to the engaging recess 12202. In this embodiment, the bracket 1220 may have a sliding groove 12204 and the lock member 1226 is movably disposed in the sliding groove 12204. The cover 1232 is disposed on the bracket 1220 and covers the sliding groove 12204, so as to prevent the lock member 1226 and the elastic member 1230 from coming off the bracket 1220. The elastic member 1230 is also disposed in the sliding groove 12204, and two ends of the elastic member 1230 abut against the lock member 1226 and the cover 1232. In this embodiment, the bracket 1220 may have two sliding grooves 12204 located at two sides of the engaging recess 12202. Furthermore, the lock module 122 may comprise two lock members 1226, two elastic members 1230 and two covers 1232, wherein the two lock members 1226 and the two elastic members 1230 are respectively disposed in the two sliding grooves 12204, and the two covers 1232 respectively cover the two sliding grooves 12204.

In this embodiment, the lock member 1226 may have an inclined surface 12260. The lock member 1226 may move with respect to the bracket 1220 between the positions shown in FIGS. 3 and 5. When the lock member 1226 is located at the position shown in FIG. 3, the lock member 1226 moves away from the engaging recess 12202 and the inclined surface 12260 protrudes from the bracket 1220. When the lock member 1226 is located at the position shown in FIG. 5, the lock member 1226 is located in the engaging recess 12202 and the inclined surface 12260 retracts into the bracket 1220.

The operating member 1228 is movably disposed on the bracket 1220. In this embodiment, the operating member 1228 may have two arm portions 12280 and a handle portion 12282, wherein the two arm portions 12280 extend from two sides of the handle portion 12282, and the operating member 1228 is U-shaped. Furthermore, the handle portion 12282 may protrude with respect to the two arm portions 12280 to form an operating space 12284 between the two arm portions 12280. The operating member 1228 is able to move with respect to the bracket 1220 between a second position shown in FIG. 3 and a first position shown in FIG. 5. In this embodiment, a moving direction of the lock member 1226 is perpendicular to a moving direction of the operating member 1228, but the disclosure is not so limited.

In this embodiment, each of the two arm portions 12280 may have a first restraining portion 12286 and a second restraining portion 12288, and the bracket 1220 may have two third restraining portions 12206 and two fourth restraining portions 12208. As shown in FIG. 5, when the operating member 1228 is located at the first position, the first restraining portion 12286 can cooperate with the third restraining portion 12206 to restrain the operating member 1228 at the first position. A user may extend a finger into the operating space 12284 and push the handle portion 12282 toward a direction of an arrow A1 to disengage the first restraining portion 12286 from the third restraining portion 12206. Then, the user may pull the handle portion 12282 upward to move the operating member 1228 to the second position shown in FIG. 3. As shown in FIG. 3, when the operating member 1228 is located at the second position, the second restraining portion 12288 can cooperate with the fourth restraining portion 12208 to restrain the operating member 1228 at the second position. The user may tilt the handle portion 12282 toward the direction of the arrow A1 to disengage the second restraining portion 12288 from the fourth restraining portion 12208. Then, the user may detach the operating member 1228 from the bracket 1220. Similarly, the user may inclinedly insert the arm portion 12280 of the operating member 1228 into a gap between the third restraining portion 12206 and the fourth restraining portion 12208 to assemble the operating member 1228 to the bracket 1220.

Before assembling the carriage 12 to the casing 10, the operating member 1228 needs to be kept at the second position, as shown in FIGS. 1 and 2. At this time, the elastic member 1230 (as shown in FIG. 4) keeps the lock member 1226 at the position shown in FIG. 2. Thus, when the operating member 1228 is located at the second position, the inclined surface 12260 of the lock member 1226 will protrude from the bracket 1220. Then, a user may align the engaging recess 12202 of the bracket 1220 with the engaging portion 100 of the casing 10 to put the carriage 12 into the casing 10, as shown in FIGS. 6 and 7. At this time, the engaging portion 100 is located in the engaging recess 12202. Then, the user may press the operating member 1228 downward, such that the operating member 1228 moves from the second position (as shown in FIGS. 6 and 7) to the first position (as shown in FIGS. 8 and 9). When the operating member 1228 moves from the second position to the first position, the operating member 1228 pushes the inclined surface 12260, such that the lock member 1226 moves into the engaging recess 12202. Thus, as shown in FIGS. 8 and 9, when the engaging portion 100 is located in the engaging recess 12202 and the lock member 1226 is located in the engaging recess 12202, the lock member 1226 restrains the engaging portion 100 in the engaging recess 12202 to lock the carriage 12 on the casing 10. Furthermore, when the operating member 1228 is located at the first position, the operating member 1228 restrains the lock member 1226 from moving, such that the lock member 1226 is located in the engaging recess 12202. Accordingly, the carriage 12 can be stably locked on the casing 10.

The lock module 122 is fixed on the housing 120 via the fixing structure 1224, engages with the engaging portion 100 of the casing 10 through the engaging recess 12202 of the bracket 1220, and isolates the bracket 1220 from the fixing structure 1224 through the damping member 1222. The damping member 1222 is capable of effectively absorbing vibrations transmitted from the casing 10 and the bracket 1220, so as to reduce the vibration energy transmitted from the casing 10 to the carriage 12. Accordingly, the disclosure can prevent vibration from causing damage to a circuit board fixed on the carriage 12.

When the operating member 1228 is located at the first position (as shown in FIG. 9), the lock member 1226 compresses the elastic member 1230 (as shown in FIG. 4). When the user wants to detach the carriage 12 from the casing 10, the user may push the handle portion 12282 of the operating member 1228 toward the direction of the arrow (as shown in FIG. 5) to disengage the first restraining portion 12286 from the third restraining portion 12206. Then, the user may pull the handle portion 12282 upward to move the operating member 1228 to the second position shown in FIG. 7. When the operating member 1228 moves from the first position to the second position, the elastic member 1230 (as shown in FIG. 4) drives the lock member 1226 to return, such that the lock member 1226 moves away from the engaging recess 12202. Thus, when the operating member 1228 is located at the second position, the operating member 1228 disengages from the lock member 1226, such that the lock member 1226 is able to move away from the engaging recess 12202 and the engaging portion 100 is able to disengage from the engaging recess 12202. Then, the user may pull the handle portion 12282 of the operating member 1228 upward to detach the carriage 12 from the casing 10.

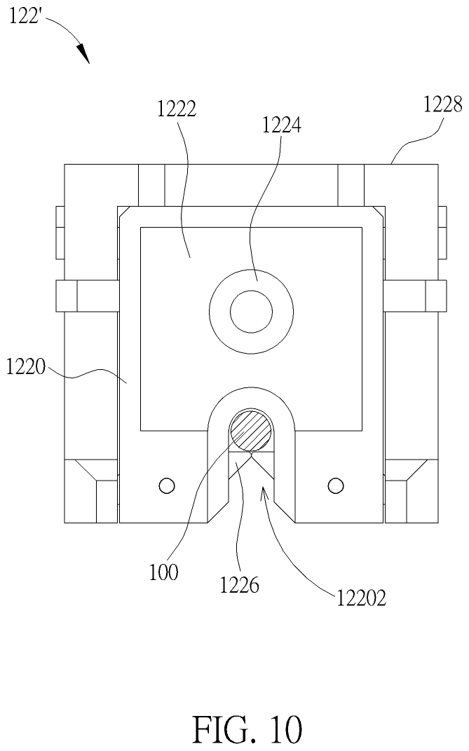

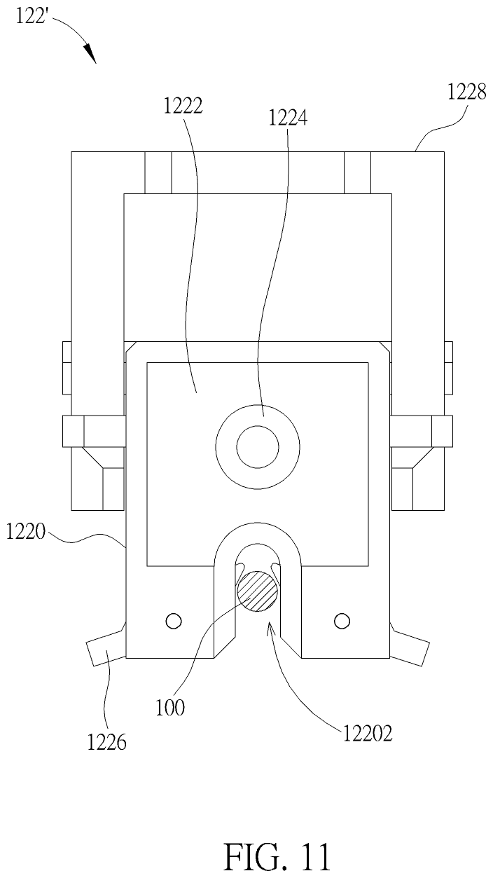

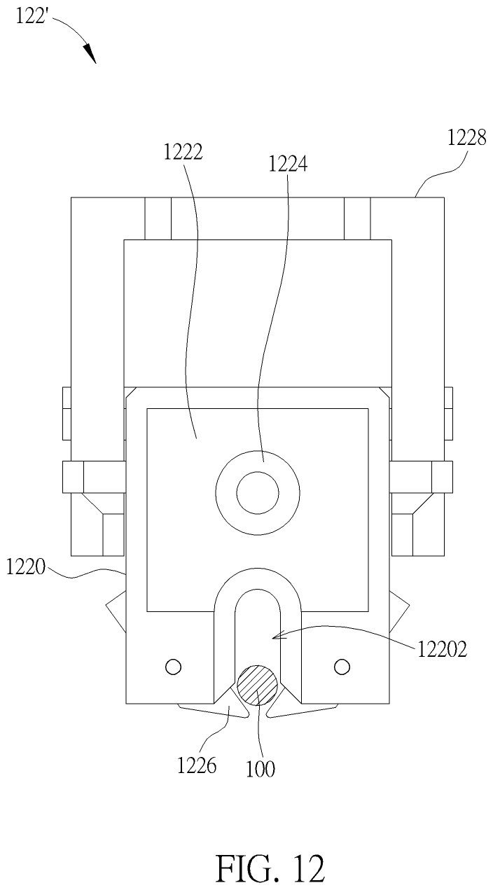

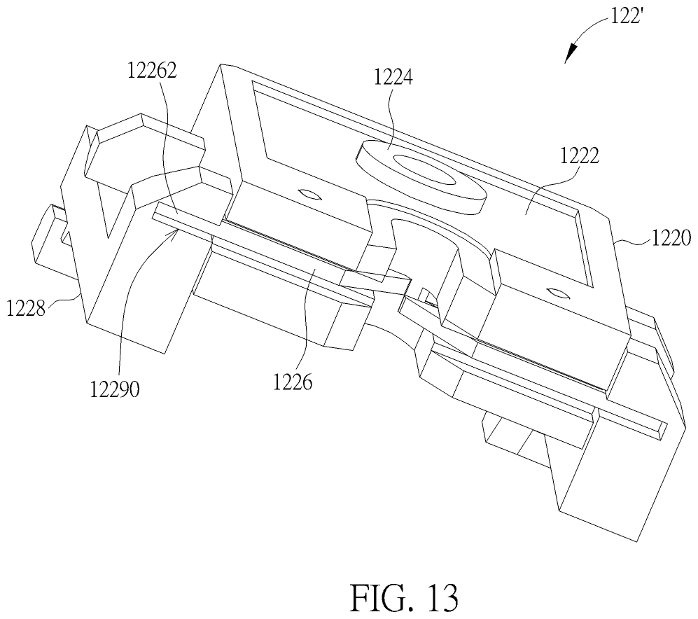

Referring to FIGS. 10 to 13, FIG. 10 is a front view illustrating a lock module 122′ according to another embodiment of the disclosure, FIG. 11 is a front view illustrating the engaging portion 100 pushing the lock member 1226 to rotate and moving into the engaging recess 12202, FIG. 12 is a front view illustrating the engaging portion 100 pushing the lock member 1226 to rotate and moving out of the engaging recess 12202, and FIG. 13 is a perspective bottom view illustrating the lock module 122′ shown in FIG. 10.

The main difference between the lock module 122′ and the aforesaid lock module 122 is that the lock member 1226 of the lock module 122′ is pivotally connected to the bracket 1220, such that the engaging portion 100 is able to push the lock member 1226 to rotate and move into or out of the engaging recess 12202, as shown in FIGS. 10 to 12. The lock module 122 shown in FIG. 1 may be replaced by the lock module 122′, so as to utilize the lock module 122′ to lock the carriage 12 on the casing 10. In this embodiment, a double torsion spring (not shown) may be disposed on the lock member 1226. As shown in FIG. 11, when the engaging recess 12202 of the bracket 1220 is aligned with the engaging portion 100 and moves downward, the engaging portion 100 will push the lock member 1226 to rotate and move into the engaging recess 12202. At this time, the lock member 1226 moves away from the engaging recess 12202. Then, the double torsion spring drives the lock member 1226 to return to a horizontal position shown in FIG. 10. At this time, the lock member 1226 is located in the engaging recess 12202 to restrain the engaging portion 100 in the engaging recess 12202. Furthermore, as shown in FIG. 12, when the bracket 1220 moves upward, the engaging portion 100 will push the lock member 1226 to rotate and move out of the engaging recess 12202. At this time, the lock member 1226 also moves away from the engaging recess 12202. Then, the double torsion spring drives the lock member 1226 to return to the horizontal position shown in FIG. 10.

In this embodiment, the operating member 1228 may have an avoidance recess 12290. As shown in FIG. 13, when the operating member 1228 is located at the first position, an end 12262 of the lock member 1226 protruding from the bracket 1220 is accommodated in the avoidance recess 12290. At this time, the engaging portion 100 shown in FIG. 10 cannot push down the lock member 1226 to rotate. Thus, when the operating member 1228 is located at the first position, the operating member 1228 restrains the lock member 1226 from rotating, such that the lock member 1226 is located in the engaging recess 12202. In other words, the operating member 1228 needs to move from the first position (as shown in FIG. 10) to the second position (as shown in FIG. 11) before the engaging portion 100 can push the lock member 1226 to rotate and move out of the engaging recess 12202.

As mentioned in the above, the disclosure disposes the damping member between the bracket and the fixing structure to isolate the bracket from the fixing structure by the damping member. The damping member is capable of effectively absorbing vibrations transmitted from the casing of the chassis and the bracket, so as to reduce the vibration energy transmitted from the casing of the chassis to the carriage. Accordingly, the disclosure can prevent vibration from causing damage to a circuit board fixed on the carriage. Furthermore, the lock module restrains the engaging portion in the engaging recess by the lock member, so as to lock the carriage on the casing. As long as the lock member moves away from the engaging recess, the engaging member is able to disengage from the engaging recess, so as to detach the carriage from the casing. Accordingly, a user can conveniently and rapidly disassemble or assemble the carriage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chassis comprising:
a casing having an engaging portion; and
a carriage comprising a housing and a lock module, the lock module comprising:
a bracket having an accommodating portion and an engaging recess;
a damping member disposed in the accommodating portion, the damping member having a hole portion;
a fixing structure disposed in the hole portion, the lock module being fixed on the housing via the fixing structure; and
a lock member movably disposed on the bracket;
wherein, when the engaging portion is located in the engaging recess and the lock member is located in the engaging recess, the lock member restrains the engaging portion in the engaging recess to lock the carriage on the casing.

2. The chassis of claim 1, wherein the lock module further comprises an operating member movably disposed on the bracket; wherein, when the operating member is located at a first position, the operating member restrains the lock member from moving, such that the lock member is located in the engaging recess; wherein, when the operating member is located at a second position, the operating member disengages from the lock member, such that the lock member is able to move away from the engaging recess and the engaging portion is able to disengage from the engaging recess.

3. The chassis of claim 2, wherein the lock member has an inclined surface; wherein, when the operating member is located at the second position, the inclined surface protrudes from the bracket; wherein, when the operating member moves from the second position to the first position, the operating member pushes the inclined surface, such that the lock member moves into the engaging recess.

4. The chassis of claim 2, wherein the operating member has two arm portions and a handle portion, the two arm portions extend from two sides of the handle portion, and the operating member is U-shaped.

5. The chassis of claim 4, wherein each of the two arm portions has a first restraining portion and a second restraining portion, the bracket has two third restraining portions and two fourth restraining portions, the first restraining portion cooperates with the third restraining portion to restrain the operating member at the first position, and the second restraining portion cooperates with the fourth restraining portion to restrain the operating member at the second position.

6. The chassis of claim 2, wherein the bracket has a sliding groove, the lock member is movably disposed in the sliding groove, and a moving direction of the lock member is perpendicular to a moving direction of the operating member.

7. The chassis of claim 6, wherein the lock module further comprises an elastic member disposed in the sliding groove; wherein, when the operating member is located at the first position, the lock member compresses the elastic member; wherein, when the operating member moves from the first position to the second position, the elastic member drives the lock member to return, such that the lock member moves away from the engaging recess.

8. The chassis of claim 2, wherein the lock member is pivotally connected to the bracket, the engaging portion is able to push the lock member to move into the engaging recess, and the operating member has an avoidance recess; wherein, when the operating member is located at the first position, an end of the lock member protruding from the bracket is accommodated in the avoidance recess.

9. The chassis of claim 1, wherein the carriage is a tray and the lock module is disposed on a side wall of the tray.

10. A carriage comprising:
a housing; and
a lock module comprising:
a bracket having an accommodating portion and an engaging recess;
a damping member disposed in the accommodating portion, the damping member having a hole portion;
a fixing structure disposed in the hole portion, the lock module being fixed on the housing via the fixing structure; and
a lock member movably disposed on the bracket.

11. The carriage of claim 10, wherein the lock module further comprises an operating member movably disposed on the bracket; wherein, when the operating member is located at a first position, the operating member restrains the lock member from moving, such that the lock member is located in the engaging recess; wherein, when the operating member is located at a second position, the operating member disengages from the lock member, such that the lock member is able to move away from the engaging recess.

12. The carriage of claim 11, wherein the lock member has an inclined surface; wherein, when the operating member is located at the second position, the inclined surface protrudes from the bracket; wherein, when the operating member moves from the second position to the first position, the operating member pushes the inclined surface, such that the lock member moves into the engaging recess.

13. The carriage of claim 11, wherein the operating member has two arm portions and a handle portion, the two arm portions extend from two sides of the handle portion, and the operating member is U-shaped.

14. The carriage of claim 13, wherein each of the two arm portions has a first restraining portion and a second restraining portion, the bracket has two third restraining portions and two fourth restraining portions, the first restraining portion cooperates with the third restraining portion to restrain the operating member at the first position, and the second restraining portion cooperates with the fourth restraining portion to restrain the operating member at the second position.

15. The carriage of claim 11, wherein the bracket has a sliding groove, the lock member is movably disposed in the sliding groove, and a moving direction of the lock member is perpendicular to a moving direction of the operating member.

16. The carriage of claim 11, wherein the lock member is pivotally connected to the bracket, the lock member is able to move into the engaging recess, and the operating member has an avoidance recess; wherein, when the operating member is located at the first position, an end of the lock member protruding from the bracket is accommodated in the avoidance recess.

17. A lock module comprising:
a bracket having an accommodating portion and an engaging recess;
a damping member disposed in the accommodating portion, the damping member having a hole portion;
a fixing structure disposed in the hole portion; and
a lock member movably disposed on the bracket.

18. The lock module of claim 17, wherein the lock module further comprises an operating member movably disposed on the bracket, and the lock member has an inclined surface; wherein, when the operating member is located at a first position, the operating member restrains the lock member from moving, such that the lock member is located in the engaging recess; wherein, when the operating member is located at a second position, the inclined surface protrudes from the bracket and the operating member disengages from the lock member, such that the lock member is able to move away from the engaging recess; wherein, when the operating member moves from the second position to the first position, the operating member pushes the inclined surface, such that the lock member moves into the engaging recess.

19. The lock module of claim 18, wherein the operating member has two arm portions and a handle portion, the two arm portions extend from two sides of the handle portion, and the operating member is U-shaped.

20. The lock module of claim 19, wherein each of the two arm portions has a first restraining portion and a second restraining portion, the bracket has two third restraining portions and two fourth restraining portions, the first restraining portion cooperates with the third restraining portion to restrain the operating member at the first position, and the second restraining portion cooperates with the fourth restraining portion to restrain the operating member at the second position.
